(19) United States
(12) Patent Application Publication
(10) Pub. No.: US 2021/0391551 A1
(43) Pub. Date: Dec. 16, 2021

(54) ORGANIC LIGHT-EMITTING LAYER, ORGANIC LIGHT-EMITTING DIODE (OLED) DISPLAY PANEL, AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Fang WANG, Wuhan, Hubei (CN)

(21) Appl. No.: 16/962,238

(22) PCT Filed: Jun. 22, 2020
(86) PCT No.: PCT/CN2020/097322

§ 371 Date: Jul. 15, 2020

(30) Foreign Application Priority Data
Jun. 10, 2020 (CN) 202010523916.0

(51) Int. Cl. H01L 51/50

(52) U.S. Cl. CPC H01L 51/5004; H01L 2251/558; H01L 51/5036; H01L 51/5012

(57) ABSTRACT

An organic light-emitting layer, an organic light-emitting diode (OLED) display panel, and a display device are provided. The organic light-emitting layer includes one or more first layers composed of at least a thermally activated delayed material, one or more second layers composed of a fluorescent material and an organic material and stacked alternately with the first layers, and one or more third layers composed of the organic material and disposed between the first layers and the second layers.

### FIELD OF INVENTION

The present disclosure relates to the technical field of display panels, and particularly to an organic light-emitting layer, an organic light-emitting diode (OLED) display panel, and a display device.

### BACKGROUND

With the improvement of economic level, flat panel televisions have become more popular, and resolution of the televisions has become higher. Organic light-emitting diodes (OLEDs) have been favored by the market in recent years because they can be made on flexible substrates. In terms of small and medium size, with the advent of folding mobile phones, the development of OLEDs can be described as entering a second burst stage. Current panels of mobile phones most commonly use a side-by-side system, wherein light-emitting layers of blue sub-pixels still use traditional blue fluorescent materials. Because the blue fluorescent materials can only use 25% of singlet excitons, their theoretical quantum efficiency is only 25%. Because the blue fluorescent materials can only use 25% of singlet excitons, they have low efficiency and high power consumption, which has always been a bottleneck hindering the development of OLED displays. Furthermore, light-emitting layers of red and green sub-pixels use phosphorescent materials. However, the phosphorescent materials comprise heavy metals, so their cost is higher. Furthermore, due to monopoly of patents of the phosphorescent materials, supply choices and prices of the phosphorescent materials have caused great problems for low-cost panels.

Thermally activated delayed fluorescence (TADF) materials are new types of pure organic electronic materials, which can simultaneously use singlet and triplet excitons generated by electrical excitation to achieve a theoretical internal quantum efficiency of 100%. However, spectral half-widths of the TADF materials are large, which is not conducive to the improvement of color gamut and color purity.

Therefore, it is indeed necessary to develop a new type of OLED display panel to overcome the defects in the prior art.

### SUMMARY OF DISCLOSURE

A purpose of the present invention is to provide an organic light-emitting layer, which can solve the problem that spectral half-widths of thermally activated delayed fluorescence (TADF) materials are large in the prior art, which is not conducive to the improvement of color gamut and color purity.

In order to achieve the above purpose, the present disclosure provides an organic light-emitting layer comprising one or more first layers composed of at least a thermally activated delayed material, one or more second layers composed of a fluorescent material and an organic material and stacked alternately with the first layers, and one or more third layers composed of the organic material and disposed between the first layers and the second layers.

Positive and negative charge carriers exist in the first layers composed of the thermally activated delayed material. Excitons are continuously diluted through processes such as diffusion, which reduces attenuation and aging of a device due to excessive exciton density.

Further, in other embodiments, a thickness of the third layers is less than or equal to a Førster energy transfer radius R₀ of the organic light-emitting layer. Calculation formula of Førster energy transfer radius R₀ is:

$${R}_{0} = 0.0211 {( \frac{{κ}^{2} Φ J}{{n}^{4}} )}^{1 \text{/} 6} ,$$

wherein k, n, Φ, and J are constants of the first layers, the second layers, and the third layers in the organic light-emitting layer, k is a dipole orientation factor of the first layers, n is a refractive index of the third layers, Φ is a photoluminescence quantum yield of the thermally activated delayed material, and J is a spectral overlap integral between donor emission and acceptor absorption of the second layers.

Therefore, when materials of the first layers, the second layers, and the third layers are selected, R₀ can be calculated. If the selected materials are unchanged, R₀ remains unchanged. Setting a distance between the first layer and the second layer to be less than or equal to R₀ can ensure effective transmission of Førster energy.

Further, in other embodiments, the organic light-emitting layer further comprises a body layer composed of the same material as the third layer. A number of the first layers is one. A number of the second layers is one. A number of the third layers is one. The first layer, the second layer, and the third layer are disposed in the body layer.

Further, in other embodiments, the first layers are composed of the thermally activated delayed material and the organic material.

Further, in other embodiments, a number of the first layers is greater than or equal to 2, a number of the second layers is greater than or equal to 2, and a number of the third layers is greater than or equal to 2.

Further, in other embodiments, a content ratio of the thermally activated delayed material is 10-50%, a content ratio of the fluorescent material is 1-10%, and a content ratio of the organic material is 40-89%.

Further, in other embodiments, singlet and triplet energies of the organic material are greater than or equal to singlet and triplet energies of the thermally activated delayed material.

Further, in other embodiments, an emission spectrum of the thermally activated delayed material overlaps with an absorption spectrum of the fluorescent material by 40%-100%.

In order to achieve the above purpose, the present disclosure further provides an organic light-emitting diode (OLED) display panel comprising a hole injection layer, a hole transport layer disposed on the hole injection layer, the organic light-emitting layer of the present invention disposed on the hole transport layer, an electron transport layer disposed on the organic light-emitting layer, and an electron injection layer disposed on the electron transport layer.

Further, in other embodiments, the OLED display panel further comprises a hole blocking layer disposed between the organic light-emitting layer and the electron transport layer, and an electron blocking layer disposed between the organic light emitting layer and the hole transport layer.

Further, in other embodiments, the organic light-emitting layer comprises a red light-emitting unit, a green light-emitting unit, and a blue light-emitting unit. A thickness of the electron blocking layer under the red light-emitting unit is greater than a thickness of the electron blocking layer under the green light-emitting unit. The thickness of the electron blocking layer under the green light-emitting unit is greater than a thickness of the electron blocking layer under the blue light emitting unit.

In order to achieve the above purpose, the present disclosure further provides a display device comprising the OLED display panel of the present invention.

Compared with the prior art, beneficial effects of the present invention are described as follows. The present disclosure provides an organic light emitting layer, an OLED display panel, and a display device. In the organic light emitting layer, a thermally activated delayed fluorescence is used as a sensitizer, and then doped with a traditional fluorescent material as a guest to emit light. This increases efficiency of a device while reducing a spectral width.

Furthermore, by calculating a Førster energy transfer radius, the traditional fluorescent material as a guest and the thermally activated delayed fluorescence are separated. This reduces exciton density in a fixed area, thereby preventing triplet-triplet annihilation (TTA), triplet-polaron annihilation (TPA), singlet-singlet annihilation (SSA), and other factors that cause device aging, thereby helping to prolong service life of the device.

### BRIEF DESCRIPTION OF DRAWINGS

Specific implementation of the present disclosure will be described in detail below in conjunction with accompanying drawings to make technical solutions and beneficial effects of the present disclosure obvious.

FIG. 1 is a schematic structural diagram of an organic light emitting layer according to Example 1 of the present disclosure.

FIG. 2 is a schematic structural diagram of an organic light-emitting diode (OLED) display panel according to Example 1 of the present disclosure.

FIG. 3 is a schematic structural diagram of an organic light emitting layer according to Example 2 of the present disclosure.

FIG. 4 is a schematic structural diagram of an organic light emitting layer according to Example 3 of the present disclosure.

### BRIEF DESCRIPTION OF DRAWINGS

organic light emitting layer—100;
first layer—10; second layer—20;
third layer—30; body layer—40;
OLED display panel—200;
hole injection layer—110; hole transport layer—120;
electron blocking layer—130; red light emitting unit—210;
green light-emitting unit—220; blue light-emitting unit—220;
hole blocking layer—140; electron transport layer—150; and
electron injection layer—160.

### DETAILED DESCRIPTION

Technical solutions in embodiments of the present disclosure will be clearly and completely described below in conjunction with accompanying drawings in the embodiments of the present disclosure. It is apparent that the described embodiments are merely a part of the embodiments of the present disclosure and not all embodiments. All other embodiments obtained by those skilled in the art based on the embodiments of the present disclosure without creative labor are within the claimed scope of the present disclosure.

In the present disclosure, unless otherwise specifically specified or limited, a structure in which a first feature is “on” or “under” a second feature may comprise an embodiment in which the first feature directly contacts the second feature, and may also comprise an embodiment in which the first feature and the second feature are not in direct contact with each other, but are contacted via an additional feature formed therebetween. Furthermore, a structure in which a first feature is “on”, “above”, or “on top of” a second feature may comprise an embodiment in which the first feature is right or obliquely “on”, “above”, or “on top of” the second feature, or just means that a sea-level elevation of the first feature is greater than a sea-level elevation of the second feature. A structure in which a first feature “under”, “below”, or “on bottom of” a second feature may include an embodiment in which the first feature is right “beneath,” “below,” or “on bottom of” the second feature, and may also comprises an embodiment in which the first feature is right or obliquely “under”, “below”, or “on bottom of” the second feature, or just means that a sea-level elevation of the first feature is less than a sea-level elevation of the second feature.

The following description provides different embodiments or examples illustrating various structures of the present invention. In order to simplify the description of the present disclosure, only components and settings of specific examples are described below. They are only examples and are not intended to limit the present invention. Furthermore, reference numerals and/or letters may be repeated in different examples of the present disclosure. Such repetitions are for simplicity and clarity, which per se do not indicate relations among the discussed embodiments and/or settings. Furthermore, the present disclosure provides various examples of specific processes and materials, but those skilled in the art can be aware of application of other processes and/or use of other materials.

### Example 1

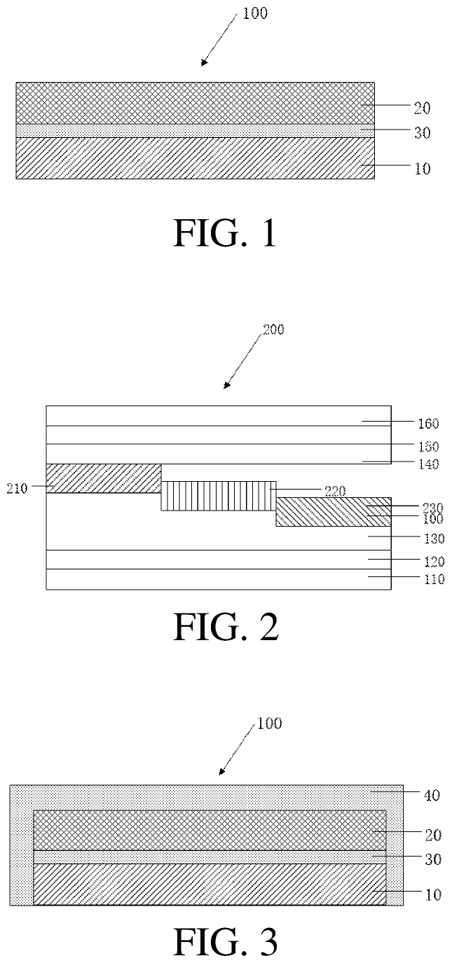

Example 1 provides an organic light-emitting layer. Please refer to FIG. 1, which is a schematic structural diagram of the organic light-emitting layer 100 according to this embodiment. The organic light emitting layer 100 comprises a first layer 10, a second layer 20, and a third layer 30.

The first layer 10 and the second layer 20 are stacked. The third layer 30 is disposed between the first layer 10 and the second layer 20.

The first layer 10 is composed of a thermally activated delayed material. The second layer 20 is composed of a fluorescent material and an organic material. The third layer 30 is composed of the organic material.

Positive and negative charge carriers exist in the first layer 10 composed of the thermally activated delayed material. Excitons are continuously diluted through processes such as diffusion, which reduces attenuation and aging of a device due to excessive exciton density.

Further, in other embodiments, a thickness of the third layer 30 is less than or equal to a Førster energy transfer radius R₀ of the organic light-emitting layer. Calculation formula of Førster energy transfer radius R₀ is:

$${R}_{0} = 0.0211 {( \frac{{κ}^{2} Φ J}{{n}^{4}} )}^{1 \text{/} 6} ,$$

wherein k, n, Φ, and J are constants of the first layers, the second layers, and the third layers in the organic light-emitting layer, k is a dipole orientation factor of the first layers, n is a refractive index of the third layers, Φ is a photoluminescence quantum yield of the thermally activated delayed material, and J is a spectral overlap integral between donor emission and acceptor absorption of the second layers.

Therefore, when materials of the first layer 10, the second layer 20, and the third layer 30 are selected, R₀ can be calculated. If the selected materials are unchanged, R₀ remains unchanged. Setting a distance between the first layer 10 and the second layer 20 to be less than or equal to R₀ can ensure effective transmission of Førster energy.

A content ratio of the thermally activated delayed material is 10-50%, a content ratio of the fluorescent material is 1-10%, and a content ratio of the organic material is 40-89%.

Singlet and triplet energies of the organic material are greater than or equal to singlet and triplet energies of the thermally activated delayed material.

Further, an emission spectrum of the thermally activated delayed material overlaps with an absorption spectrum of the fluorescent material by 40%-100%.

The present disclosure further provides an organic light-emitting diode (OLED) display panel. Please refer to FIG. 2, which is a schematic structural diagram of the OLED display panel 200 according to this embodiment. The OLED display panel 200 comprises a hole injection layer 110, a hole transport layer 120, an electron blocking layer 130, the organic light emitting layer 100 of the present invention, a hole blocking layer 140, an electron transport layer 150, and an electron injection layer 160.

The hole transport layer 120 is disposed on the hole injection layer 110. The electron blocking layer 130 is disposed on the hole transport layer 120. The organic light-emitting layer 100 of the present invention is disposed on the electron blocking layer 130. The hole blocking layer 140 is disposed on the organic light emitting layer 100. The electron transport layer 150 is disposed on the hole blocking layer 140. The electron injection layer 160 is disposed on the electron transport layer 150.

The organic light-emitting layer 100 comprises a red light-emitting unit 210, a green light-emitting unit 220, and a blue light-emitting unit 230. A thickness of the electron blocking layer 130 under the red light-emitting unit 210 is greater than a thickness of the electron blocking layer 130 under the green light-emitting unit 220. The thickness of the electron blocking layer 130 under the green light-emitting unit 220 is greater than a thickness of the electron blocking layer 130 under the blue light emitting unit 230.

In order to achieve the above purpose, the present disclosure further provides a display device comprising the OLED display panel of the present invention.

### Example 2

An organic light-emitting layer in this embodiment also comprises a first layer, a second layer, and a third layer, and its structure is substantially the same as the corresponding structure of Example 1. For the same structure, please refer to the corresponding description in Example 1, which will not be described in detail herein. The main difference between the two is that this organic light-emitting layer further comprises a body layer.

Please refer to FIG. 3, which is a schematic structural diagram of the organic light emitting layer 100 according to this embodiment. A number of the first layer 10 is one. A number of the second layer 20 is one. A number of the third layer 30 is one. The first layer 10, the second layer 20, and the third layer 30 are disposed in the body layer 40. The body layer 40 is composed of the same material as the third layer 30.

### Example 3

An organic light-emitting layer in this embodiment also comprises first layers, second layers, and third layers, and its structure is substantially the same as the corresponding structure of Example 1. For the same structure, please refer to the corresponding description in Example 1, which will not be described in detail herein. The main difference between the two is that these first layers 10 are composed of a thermally activated delayed material, and an organic material as used in the third layers 30. The thermally activated delayed material and the organic material are doped in the first layers 10. A number of the first layers 10 is greater than or equal to 2, a number of the second layers 20 is greater than or equal to 2, and a number of the third layers 30 is greater than or equal to 2.

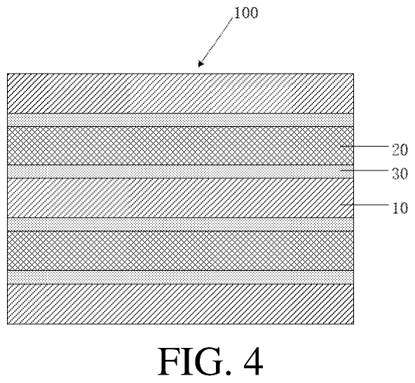

Please refer to FIG. 4, which is a schematic structural diagram of the organic light emitting layer 100 according to this embodiment. A distance between the first layer 10 and the second layer 20 is also less than or equal to R₀. This arrangement further reduces exciton density, increases device efficiency, and prevents device attenuation.

Compared with the prior art, beneficial effects of the present invention are described as follows. The present disclosure provides an organic light emitting layer, an OLED display panel, and a display device. In the organic light emitting layer, a thermally activated delayed fluorescence is used as a sensitizer, and then doped with a traditional fluorescent material as a guest to emit light. This increases efficiency of a device while reducing a spectral width.

Furthermore, by calculating a Førster energy transfer radius, the traditional fluorescent material as a guest and the thermally activated delayed fluorescence are separated. This reduces exciton density in a fixed area, thereby preventing triplet-triplet annihilation (TTA), triplet-polaron annihilation (TPA), singlet-singlet annihilation (SSA), and other factors that cause the device aging, thereby helping to prolong service life of the device.

In the above embodiments, the description of each embodiment has its own emphasis. For parts not detailed in one embodiment, reference may be made to the related descriptions in other embodiments.

The organic light emitting layer, the OLED display panel, and the display device provided by the embodiments of the present disclosure are described in detail above. The present disclosure uses specific examples to describe principles and embodiments of the present application. The above description of the embodiments is only for helping to understand the technical solutions of the present disclosure and its core ideas. It should be understood by those skilled in the art that they can modify the technical solutions recited in the foregoing embodiments, or replace some of technical features in the foregoing embodiments with equivalents. These modifications or replacements do not cause essence of corresponding technical solutions to depart from the scope of the technical solutions of the embodiments of the present disclosure.

1. An organic light-emitting layer, comprising:
one or more first layers composed of at least a thermally activated delayed material;
one or more second layers composed of a fluorescent material and an organic material and stacked alternately with the first layers; and
one or more third layers composed of the organic material and disposed between the first layers and the second layers.

2. The organic light-emitting layer according to claim 1, wherein a thickness of the third layers is less than or equal to a Førster energy transfer radius R₀ of the organic light-emitting layer, and calculation formula of Førster energy transfer radius R₀ is:
$${R}_{0} = 0.0211 {( \frac{{κ}^{2} Φ J}{{n}^{4}} )}^{1 \text{/} 6} ,$$
wherein k, n, Φ, and J are constants of the first layers, the second layers, and the third layers in the organic light-emitting layer, k is a dipole orientation factor of the first layers, n is a refractive index of the third layers, Φ is a photoluminescence quantum yield of the thermally activated delayed material, and J is a spectral overlap integral between donor emission and acceptor absorption of the second layers.

3. The organic light-emitting layer according to claim 2, further comprising a body layer composed of the same material as the third layer, wherein a number of the first layers is one, a number of the second layers is one, a number of the third layers is one, and the first layer, the second layer, and the third layer are disposed in the body layer.

4. The organic light-emitting layer according to claim 1, wherein the first layers are composed of the thermally activated delayed material and the organic material.

5. The organic light-emitting layer according to claim 4, wherein a number of the first layers is greater than or equal to 2, a number of the second layers is greater than or equal to 2, and a number of the third layers is greater than or equal to 2.

6. The organic light-emitting layer according to claim 1, wherein a content ratio of the thermally activated delayed material is 10-50%, a content ratio of the fluorescent material is 1-10%, and a content ratio of the organic material is 40-89%.

7. The organic light-emitting layer according to claim 1, wherein singlet and triplet energies of the organic material are greater than or equal to singlet and triplet energies of the thermally activated delayed material.

8. The organic light-emitting layer according to claim 1, wherein an emission spectrum of the thermally activated delayed material overlaps with an absorption spectrum of the fluorescent material by 40%-100%.

9. An organic light-emitting diode (OLED) display panel, comprising:
a hole injection layer;
a hole transport layer disposed on the hole injection layer;
an organic light-emitting layer disposed on the hole transport layer, and comprising one or more first layers composed of at least a thermally activated delayed material, one or more second layers composed of a fluorescent material and an organic material and stacked alternately with the first layers, and one or more third layers composed of the organic material and disposed between the first layers and the second layer;
an electron transport layer disposed on the organic light-emitting layer; and
an electron injection layer disposed on the electron transport layer.

10. The OLED display panel according to claim 9, wherein a thickness of the third layers is less than or equal to a Førster energy transfer radius R₀ of the organic light-emitting layer, and calculation formula of Førster energy transfer radius R₀ is:
$${R}_{0} = 0.0211 {( \frac{{κ}^{2} Φ J}{{n}^{4}} )}^{1 \text{/} 6} ,$$
wherein k, n, Φ, and J are constants of the first layers, the second layers, and the third layers in the organic light-emitting layer, k is a dipole orientation factor of the first layers, n is a refractive index of the third layers, Φ is a photoluminescence quantum yield of the thermally activated delayed material, and J is a spectral overlap integral between donor emission and acceptor absorption of the second layers.

11. The OLED display panel according to claim 10, wherein the organic light-emitting layer further comprises a body layer composed of the same material as the third layer, a number of the first layers is one, a number of the second layers is one, a number of the third layers is one, and the first layer, the second layer, and the third layer are disposed in the body layer.

12. The OLED display panel according to claim 9, wherein the first layers are composed of the thermally activated delayed material and the organic material.

13. The OLED display panel according to claim 12, wherein a number of the first layers is greater than or equal to 2, a number of the second layers is greater than or equal to 2, and a number of the third layers is greater than or equal to 2.

14. The OLED display panel according to claim 9, wherein a content ratio of the thermally activated delayed material is 10-50%, a content ratio of the fluorescent material is 1-10%, and a content ratio of the organic material is 40-89%.

15. The OLED display panel according to claim 9, wherein singlet and triplet energies of the organic material are greater than or equal to singlet and triplet energies of the thermally activated delayed material.

16. The OLED display panel according to claim 9, wherein an emission spectrum of the thermally activated delayed material overlaps with an absorption spectrum of the fluorescent material by 40%-100%.

17. A display device, comprising an organic light-emitting diode (OLED) display panel, wherein the OLED display panel comprises:
a hole injection layer;
a hole transport layer disposed on the hole injection layer;
an organic light-emitting layer disposed on the hole transport layer, and comprising one or more first layers composed of at least a thermally activated delayed material, one or more second layers composed of a fluorescent material and an organic material and stacked alternately with the first layers, and one or more third layers composed of the organic material and disposed between the first layers and the second layer;
an electron transport layer disposed on the organic light-emitting layer; and
an electron injection layer disposed on the electron transport layer.

18. The display device according to claim 17, wherein a thickness of the third layers is less than or equal to a Førster energy transfer radius R₀ of the organic light-emitting layer, and calculation formula of Førster energy transfer radius R₀ is:
$${R}_{0} = 0.0211 {( \frac{{κ}^{2} Φ J}{{n}^{4}} )}^{1 \text{/} 6} ,$$
wherein k, n, Φ, and J are constants of the first layers, the second layers, and the third layers in the organic light-emitting layer, k is a dipole orientation factor of the first layers, n is a refractive index of the third layers, Φ is a photoluminescence quantum yield of the thermally activated delayed material, and J is a spectral overlap integral between donor emission and acceptor absorption of the second layers.

19. The display device according to claim 18, wherein the organic light-emitting layer further comprises a body layer composed of the same material as the third layer, a number of the first layers is one, a number of the second layers is one, a number of the third layers is one, and the first layer, the second layer, and the third layer are disposed in the body layer.

20. The display device according to claim 17, wherein the first layers are composed of the thermally activated delayed material and the organic material.
